(19) United States
(12) Patent Application Publication
(10) Pub. No.: US 2025/0228029 A1
(43) Pub. Date: Jul. 10, 2025

(54) SEMICONDUCTOR DEVICE AND METHOD OF MANUFACTURING SEMICONDUCTOR DEVICE

(71) Applicant: SONY SEMICONDUCTOR SOLUTIONS CORPORATION, Kanagawa (JP)

(72) Inventors: Nobutoshi FUJII, Kanagawa (JP); Suguru SAITO, Kanagawa (JP); Tokihisa KANEGUCHI, Kanagawa (JP); Tadamasa SHIOYAMA, Kanagawa (JP)

(73) Assignee: SONY SEMICONDUCTOR SOLUTIONS CORPORATION, Kanagawa (JP)

(21) Appl. No.: 18/847,586

(22) PCT Filed: Feb. 6, 2023
(86) PCT No.: PCT/JP2023/003848

§ 371 Date: Sep. 16, 2024

(30) Foreign Application Priority Data
Mar. 30, 2022 (JP) 2022-056868

(51) Int. Cl. H10F 39/00; H10F 77/20

(52) U.S. Cl. CPC H10F 39/811; H10F 39/026; H10F 39/8057; H10F 77/20

(57) ABSTRACT

To reduce the alignment accuracy required in arrangement of shields. A semiconductor device includes a first substrate and a second substrate. The first substrate includes a plurality of first wirings insulated from each other, a plurality of first electrodes connected to the first wirings and insulated from each other, and a first shield electrode arranged at least between the plurality of first electrodes and insulated from the first electrode. The second substrate includes a plurality of second wirings insulated from each other, a plurality of second electrodes connected to the second wirings and insulated from each other, and a second shield electrode arranged at least between the plurality of second electrodes and insulated from the second electrode. The first electrode and the second electrode are electrically connected by hybrid bonding. The first shield electrode and the second shield electrode are electrically connected by hybrid bonding to form a first shield.

### TECHNICAL FIELD

The present disclosure relates to a semiconductor device and a method of manufacturing a semiconductor device.

### BACKGROUND ART

In a case of densely arranging electrically controlled elements such as light receiving elements in a solid-state imaging device, it is necessary to miniaturize the arrangement area per element. In order to achieve further miniaturization of the solid-state imaging device, in some cases, a wiring, a logic circuit, and the like are arranged in a semiconductor layer different from the semiconductor layer of the pixel array in which the light receiving elements are arranged, and a three-dimensional structure in which these semiconductor layers are laminated by hybrid bonding so as to be electrically connected to each other appropriately may be adopted.

In order to increase the resolution of an image to be captured or in order to miniaturize a semiconductor chip to which an imaging element belongs, it is required to further miniaturize a light receiving pixel including a light receiving element. In a case of arranging the light receiving pixels at a high density, it is necessary to miniaturize the connection surface for the connection between the semiconductor layers and the wiring (signal line) to the connection surface. Accordingly, it is also necessary to miniaturize the width of the oxide film between the wirings, but the miniaturization may cause problems such as parasitic capacitance. In order to avoid this situation, for example, it is conceivable to arrange a grounded conductor wiring (shield) between the wirings.

However, when the shields are appropriately arranged, there is a possibility that a pad provided as a contact surface of a signal line of one semiconductor layer may come into contact with a shield of the other semiconductor layer at a timing when the semiconductor layers are connected to each other. This may cause a problem that the required alignment accuracy is very high.

### CITATION LIST

### Patent Document

Patent Document 1: Japanese Patent Application Laid-Open No. 2020-088380

### SUMMARY OF THE INVENTION

### Problems to be Solved by the Invention

Therefore, the present disclosure provides a semiconductor device that reduces the alignment accuracy required in arrangement of shields.

### Solutions to Problems

According to one embodiment, a semiconductor device includes a first substrate and a second substrate. The first substrate includes:
a plurality of first wirings insulated from each other;
a plurality of first electrodes connected to the first wirings and insulated from each other; and
a first shield electrode arranged at least between the plurality of first electrodes and insulated from the first electrode.

The second substrate includes:
a plurality of second wirings insulated from each other;
a plurality of second electrodes connected to the second wirings and insulated from each other; and
a second shield electrode arranged at least between the plurality of second electrodes and insulated from the second electrode.

The first electrode and the second electrode are electrically connected by hybrid bonding, and

The first shield electrode and the second shield electrode are electrically connected by hybrid bonding to form a first shield.

The first substrate may further include, between the first shield and the first wiring, or between the first shield and the first wiring and the first electrode, a second shield that is a conductor insulated from the first wiring, the first electrode, the first shield, and a bonding surface between the first substrate and the second substrate.

The second shield may be grounded.

The second shield may be arranged in the insulator so as not to be connected to any potential.

The potential of the first shield may be controlled to a predetermined potential.

The first shield may be grounded.

The first shield may be controlled to a predetermined potential on the second substrate side.

The first shield may be grounded.

A plurality of the first shield electrodes may be arranged while being insulated between the adjacent first electrodes, and the second shield electrode may be electrically connected to at least one of the plurality of first shield electrodes.

At a bonding surface between the first substrate and the second substrate, a distance between the first shield electrodes may be shorter than a width of the second shield electrode.

At a bonding surface between the first substrate and the second substrate, a width of the first electrode may be narrower than a width of the second electrode, and a distance between the second electrode and the second shield electrode may be shorter than a width of the first electrode.

The first wiring, the first electrode, the first shield electrode, the second wiring, the second electrode, the second shield electrode, and the first shield may include copper.

The second shield may include copper.

The first substrate may include a plurality of pixels each including a photodiode, and each of the pixels may be connected to the first electrode via the first wiring.

The second substrate may include a plurality of pixel circuits that process signals output from the pixels, and each of the pixel circuits may be connected to the second electrode via the second wiring.

The hybrid bonding may be bonding in which at least a part of an electrode formed in an interlayer insulating film on a bonding surface of the first substrate and an electrode formed in an interlayer insulating film on a bonding surface of the second substrate are directly connected to each other.

According to one embodiment, a method of manufacturing a semiconductor device is a method of manufacturing a semiconductor device formed by laminating a first substrate and a second substrate, the method including:
forming, on the first substrate, a plurality of first wirings, a plurality of first electrodes connected to the first wirings, and a plurality of first shield electrodes insulated from the first wirings and the first electrodes between the adjacent first electrodes;
forming, on the second substrate, a plurality of second wirings, a plurality of second electrodes connected to the second wirings, and the second shield electrode insulated from the second wirings and the second electrodes between the adjacent second electrodes; and
electrically connecting the first electrode and the second electrode, and at least one of the first electrodes and the second shield electrode.

The electrode of the first substrate and the electrode of the second substrate may be electrically connected by hybrid bonding.

The first substrate and the second substrate may be bonded in a form of chip on chip (CoC), chip on wafer (CoW), or wafer on wafer (WoW).

A photodiode may be formed on the first substrate, a pixel circuit may be formed on the second substrate, and the first electrode connected to the photodiode via the first wiring and the second electrode connected to the pixel circuit via the second wiring may be electrically connected.

### BRIEF DESCRIPTION OF DRAWINGS

FIG. 1 is a diagram schematically illustrating a semiconductor device according to an embodiment.

FIG. 2 is a diagram schematically illustrating the semiconductor device according to the embodiment.

FIG. 3 is a cross-sectional view schematically illustrating a bonding region of the semiconductor device according to the embodiment.

FIG. 4 is a diagram illustrating a plane A-A of FIG. 3.

FIG. 5 is a diagram illustrating a plane B-B of FIG. 3.

FIG. 6 is a diagram illustrating a plane B-B of FIG. 3.

FIG. 7 is a cross-sectional view schematically illustrating a bonding region of the semiconductor device according to the embodiment.

FIG. 8 is a cross-sectional view schematically illustrating a bonding region of the semiconductor device according to the embodiment.

FIG. 9 is a cross-sectional view schematically illustrating a bonding region of the semiconductor device according to the embodiment.

FIG. 10 is a diagram illustrating an example of the semiconductor device according to the embodiment.

FIG. 11 is a cross-sectional view schematically illustrating a semiconductor device according to the embodiment.

FIG. 12 is a cross-sectional view schematically illustrating a semiconductor device according to the embodiment.

FIG. 13 is a diagram illustrating an example of a manufacturing process of the semiconductor device according to the embodiment.

FIG. 14 is a diagram illustrating an example of a manufacturing process of the semiconductor device according to the embodiment.

FIG. 15 is a diagram illustrating an example of a manufacturing process of the semiconductor device according to the embodiment.

FIG. 16 is a block diagram illustrating an example of a schematic configuration of a vehicle control system.

FIG. 17 is an explanatory diagram illustrating an example of installation positions of an outside-vehicle information detecting section and an imaging section.

### MODE FOR CARRYING OUT THE INVENTION

Hereinafter, an embodiment of the present disclosure will be described with reference to the drawings. The drawings are used for description, and the shape and size of the configuration of each unit in the actual device, the ratio of the size to other configurations, and the like are not necessarily as illustrated in the drawings. Furthermore, since the drawings are illustrated in a simplified manner, configurations necessary for implementation other than those illustrated in the drawings are appropriately provided.

In addition, in the description, wirings, electrodes, and the like include conductors, but as a non-limiting example, the conductors may be any of copper (Cu), silver (Ag), gold (Au), or aluminum (Al), or may be other conductors having an appropriate conductivity.

### Configuration of Semiconductor Device

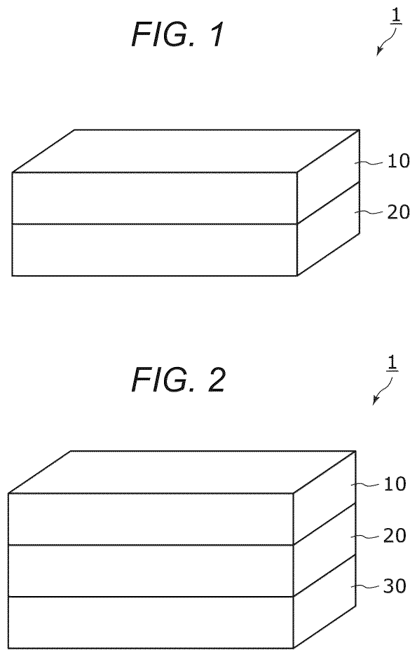

FIG. 1 is a diagram illustrating a non-limiting example of a semiconductor device according to an embodiment; The semiconductor device 1 includes a first substrate 10 and a second substrate 20. The semiconductor device 1 may be a one-chip semiconductor formed by electrically connecting the first substrate 10 and the second substrate 20 appropriately.

The first substrate 10 and the second substrate 20 have semiconductor layers, and wirings of these semiconductor layers are electrically connected to each other. The first substrate 10 and the second substrate 20 may be semiconductor layers having different functions. The first substrate 10 and the second substrate 20 are electrically connected to each other by, for example, hybrid bonding between electrodes on a bonding surface.

Note that hybrid bonding is a method of bonding a plurality of semiconductor layers. In hybrid bonding, a plurality of semiconductor layers is formed in a state in which an electrode in a wiring layer and an interlayer insulating film are exposed on a bonding surface of a substrate, and at least some electrodes in the respective semiconductor layers exposed on the bonding surface are directly connected and bonded to each other, thereby generating one laminated semiconductor.

The semiconductor device 1 may form a solid-state imaging element as a non-limiting example. In this case, the first substrate 10 may include, for example, an optical system and a light receiving element such as a photodiode that outputs an analog signal corresponding to the intensity of the received light. The second substrate 20 may include at least one of a pixel circuit that appropriately processes a signal output from the light receiving element, a signal processing circuit, an image processing circuit, a storage circuit, or the like. Information of the light received by the first substrate 10 is output to the second substrate 20 via an electrode electrically connected appropriately at a bonding surface between the first substrate 10 and the second substrate 20.

FIG. 2 is a diagram illustrating another non-limiting example of the semiconductor device 1. The semiconductor device 1 may include a third substrate 30 in addition to the first substrate 10 and the second substrate 20. Similarly in the case of FIG. 2, the first substrate 10 and the second substrate 20, and the second substrate 20 and the third substrate 30 are electrically connected appropriately. As a non-limiting example, this electrical connection is formed by hybrid bonding of electrodes at the bonding surfaces of the respective substrates.

In the following description, as a non-limiting example, a configuration in which the semiconductor device 1 includes two types of semiconductor layers including the first substrate 10 and the second substrate 20 will be described, but a bonding surface between the second substrate 20 and the third substrate 30 may also be subjected to similar processing.

### First Embodiment

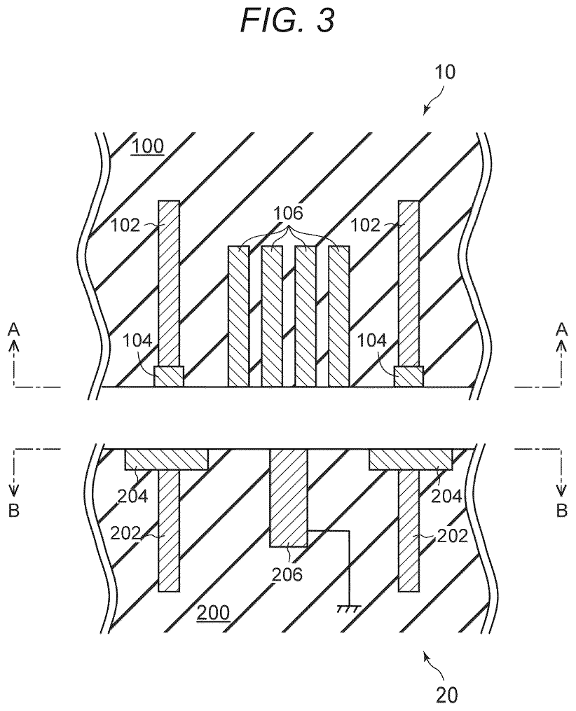

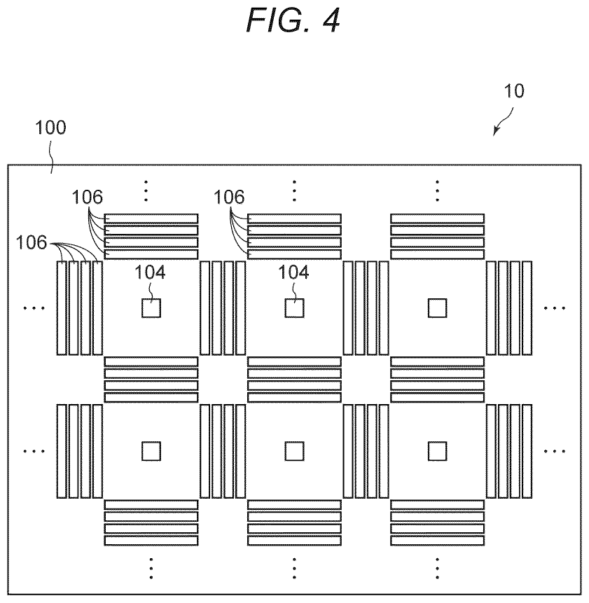

FIG. 3 is a cross-sectional view illustrating a part of a bonding region between electrodes of the first substrate 10 and electrode of the second substrate 20 according to an embodiment in a separated manner.

The first substrate 10 includes an insulator 100, a first wiring 102, a first electrode 104, and a first shield electrode 106.

The insulator 100 is an insulating film (oxide film) formed on the first substrate 10 such that conductors such as wirings and electrodes are not electrically connected to each other. The insulator 100 may include, for example, SiO₂ obtained by oxidizing a silicon substrate.

The first wiring 102 is a wiring for propagating a signal from or to a component (not illustrated) of the first substrate 10. As an example of a case where the semiconductor device 1 is a solid-state imaging element, the first wiring 102 may be a conductor that propagates a signal output from a light receiving element such as a photodiode. A plurality of first wirings 102 may be insulated from each other, or may be electrically connected appropriately as necessary.

The first electrode 104 is an electrode connected to the first wiring 102 and electrically connected to the second substrate 20. That is, a signal propagated through the first wiring 102 is output to the second substrate 20 via the first electrode 104. Conversely, a signal output from the second substrate 20 may be propagated to the first wiring 102 via the first electrode 104. A plurality of first electrodes 104 is arranged to be insulated from each other by the insulator 100.

The first shield electrode 106 is an electrode arranged at least between the first electrodes 104 while being insulated from the first electrodes 104. Moreover, a plurality of the first shield electrodes 106 is arranged between the first electrodes 104 so as to be insulated by the insulator 100. As illustrated in FIG. 3, the first shield electrode 106 is arranged in a floating state on the first substrate 10, that is, in a state where their potentials are not controlled.

Note that while four first shield electrodes 106, for example, are illustrated between a set of two first electrodes 104, the present invention is not limited thereto, as long as there is a plurality of the first shield electrodes 106.

The second substrate 20 includes an insulator 200, a second wiring 202, a second electrode 204, and a second shield electrode 206.

The insulator 200 is an insulating film formed on the second substrate 20 such that conductors such as wirings and electrodes are not electrically connected to each other. Similarly to the insulator 100, the insulator 200 may include, for example, SiO₂.

The second wiring 202 is a wiring for propagating a signal from or to a component (not illustrated) of the second substrate 20. As an example of a case where the semiconductor device 1 is a solid-state imaging element, the second wiring 202 is a wiring that propagates a signal from a photodiode or the like acquired from the first substrate 10 to a circuit that appropriately processes the signal. A plurality of second wirings 202 may be insulated from each other, or may be electrically connected appropriately as necessary.

The second electrode 204 is an electrode connected to the second wiring 202 and electrically connected to the first substrate 10. That is, a signal propagated through the second wiring 202 may be output to the first substrate 10 via the second electrode 204, or a signal output from the first substrate 10 may be propagated to the second wiring 202 via the second electrode 204. A plurality of second electrodes 204 is arranged to be insulated from each other by the insulator 200.

The second shield electrode 206 is an electrode arranged at least between the second electrodes 204 while being insulated from the second electrodes 204. The potential of the second shield electrode 206 is controlled. As a non-limiting example, the potential of the second shield electrode 206 is controlled to a predetermined potential. As a non-limiting example, the predetermined potential may be a ground potential as illustrated in FIG. 3.

The first substrate 10 and the second substrate 20 are formed, for example, by electrically connecting at least the first electrode 104 and the second electrode 204, and the first shield electrode 106 and the second shield electrode 206 by hybrid bonding. The semiconductor device 1 includes a first shield in which the first shield electrode 106 and the second shield electrode 206 are hybrid bonded at least between the bonding regions of the first electrode 104 and the second electrode 204.

Referring to FIG. 3, as an example, the first shield is controlled to an appropriate potential such as a ground potential on the second substrate 20 side via the second electrode 204.

FIG. 4 is a diagram illustrating the first substrate 10 on an A-A surface of FIG. 3, that is, the bonding surface. In the bonding surface, a plurality of first electrodes 104 and a plurality of first shield electrodes 106 arranged between two first electrodes 104 are arranged on the first substrate 10.

As illustrated in FIG. 4, the electrodes and wirings illustrated in FIG. 3 may be repeatedly arranged on the first substrate 10. While the solid-state imaging element has been described as an example, the aspect of the present disclosure can also be applied to a case where there is a wiring or the like that periodically appears as described above. Alternatively, the aspect of the present disclosure can also be applied to a semiconductor device having a structure such as a fine wiring even if the structure is not periodic.

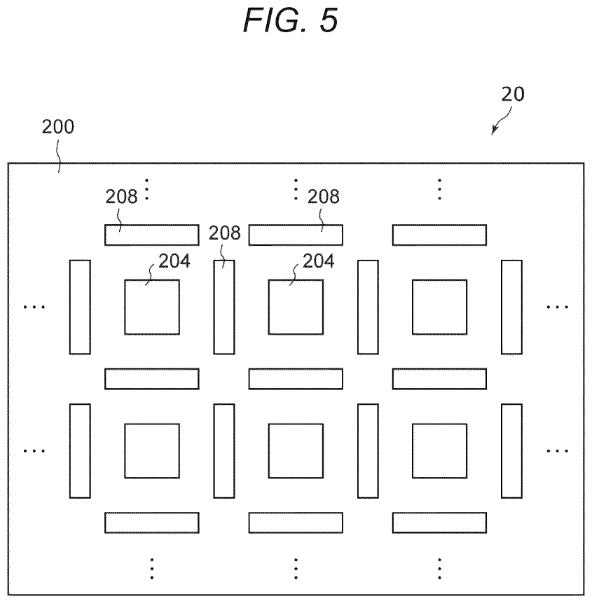

FIG. 5 is a diagram illustrating the second substrate 20 on a B-B surface of FIG. 3, that is, the bonding surface. In the bonding surface, a plurality of second electrodes 204 and a second shield electrode 206 arranged between two second electrodes 204 are arranged on the second substrate 20.

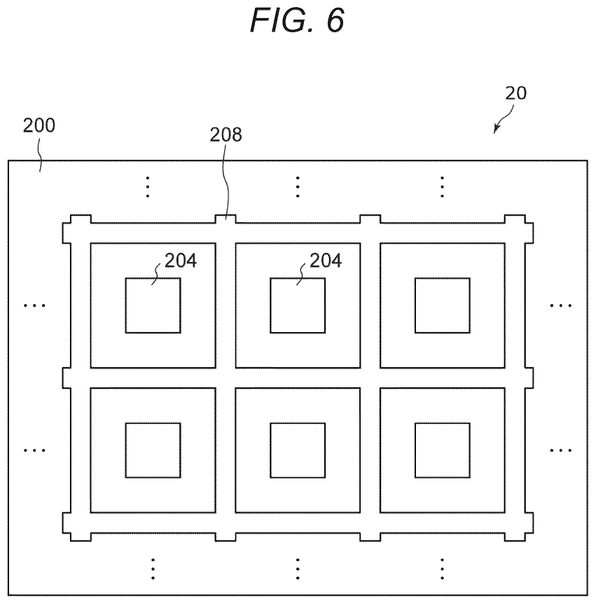

FIG. 6 is a diagram illustrating another example of the second substrate 20 on the B-B surface of FIG. 3, that is, the bonding surface. In the bonding surface, a plurality of second electrodes 204 and a second shield electrode 206 arranged between two second electrodes 204 are arranged on the second substrate 20. Unlike FIG. 5, the second electrode 204 may be formed in a connected manner.

As illustrated in FIGS. 3 to 6, as an example, the first electrode 104 may occupy a region smaller than the second electrode 204 at the bonding surface. That is, the width of the first electrode 104 may be smaller than the width of the second electrode 204 at the bonding surface. Moreover, the distance between the second electrode 204 and the second shield electrode 206 may be shorter than the width of the first electrode 104.

Furthermore, the width of each of the first shield electrodes 106 may be narrower than the width of the second shield electrode 206 at the bonding surface. In addition, the distance between adjacent first shield electrodes 106 may be shorter than the width of the second shield electrode at the bonding surface.

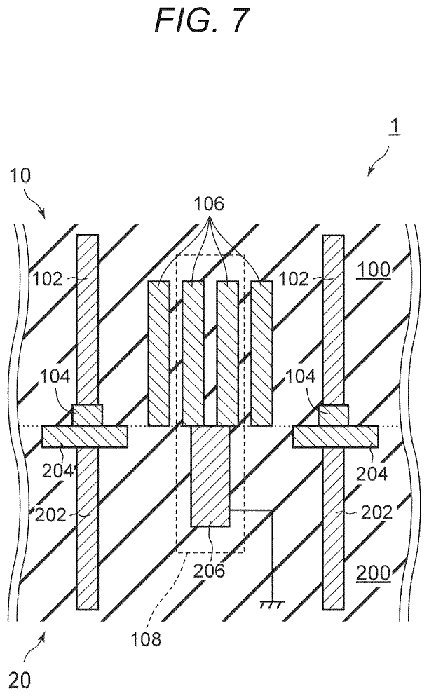

FIG. 7 is a cross-sectional view illustrating the bonding region of the semiconductor device 1 in an unseparated state. While the boundary between the first substrate 10 and the second substrate 20 is indicated by a supplementary dotted line, the first substrate 10 and the second substrate 20 are bonded by hybrid bonding. As indicated by a broken line, the first shield electrode 106 and the second shield electrode 206 form one first shield 108 in a bonded state.

As a non-limiting example, the first shield 108 is grounded on the second substrate 20 side. The first shield 108 is arranged at least between the first electrodes 104 and between the second electrodes 204. Therefore, the first shield 108 can curb generation of parasitic capacitance or the like between the first electrodes 104 and between the second electrodes 204. Therefore, in the semiconductor device 1 in which the first substrate 10 and the second substrate 20 are laminated, the first shield 108 can greatly curb generation of noise and other signal degradation at the bonding surface as compared with a case where the first shield 108 is not provided.

As a non-limiting example, the example of FIG. 7 illustrates a state in which there is no misalignment in bonding of the first substrate 10 and the second substrate 20 in the manufacturing process. In the case of the arrangement of the electrodes of the first substrate 10 and the second substrate 20 in the present disclosure, an appropriate shield can be similarly formed even when a misalignment occurs in the manufacturing process.

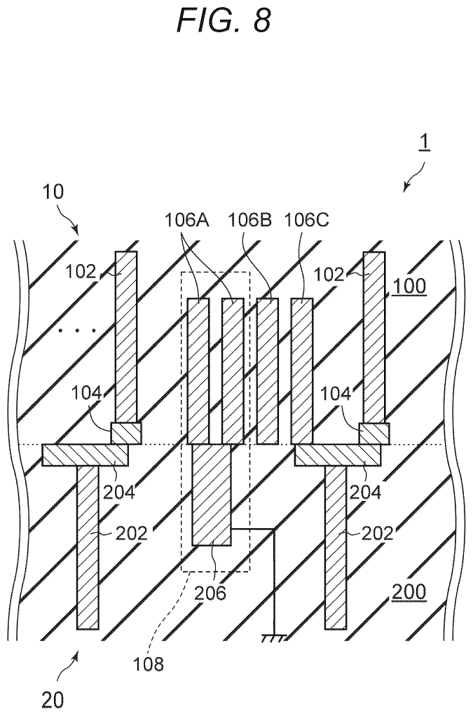

FIG. 8 is a cross-sectional view illustrating a bonding region of the semiconductor device 1 according to the embodiment. The first shield electrode 106 includes a first shield electrode 106A electrically connected to the second shield electrode 206, that is, forming the first shield 108, a first shield electrode 106B not electrically connected to an electrode in the second substrate 20, and a first shield electrode 106C electrically connected to the second electrode 204.

In this case, the first shield electrode 106C has the same potential as the first wiring 102, the first electrode 104, the second wiring 202, and the second electrode 204 on the right side. However, since the first shield electrode 106C is not electrically connected to any wiring or electrode in the first substrate 10, the probability that the signal is affected by degradation such as noise is particularly low.

Since the first shield electrode 106B is not electrically connected to any wiring and electrode in the semiconductor device 1, electrons move in the electrode, but the influence on other wirings and electrodes is small. The first shield electrode 106B is adjacent to the first shield electrode 106A whose potential is controlled on one surface via the insulator 100, and is adjacent to the first shield electrode 106C whose potential varies depending on the signal potential on the other surface via the insulator 100. With such an arrangement, potential bias in the first shield electrode 106B is unlikely to occur, and the possibility of the occurrence of potential bias due to signal degradation such as noise is low.

The first shield electrode 106A is connected to the second shield electrode 206 to form the first shield 108. Similarly to the case of FIG. 7, the first shield 108 can function as a shield that prevents signal degradation between the first electrodes 104 and between the second electrodes 204 at the bonding surface.

As described above, even if a misalignment occurs at the bonding timing, the electrode functioning as a shield and the wiring can be appropriately arranged by arranging the electrodes as in the present embodiment.

Note that, as can be seen with reference to FIGS. 4 and 6, although the one-dimensional misalignment has been described above, an appropriate shield electrode can be arranged between the signal lines even in a case where a two-dimensional misalignment occurs.

This misalignment can be allowed up to a range in which the first electrode 104 is in contact with the second electrode 204. By mounting the first substrate 10 and the second substrate 20 as described above, the region in the bonding surface of the second shield electrode 206 can be made narrower than the region in the bonding surface of the first shield electrode 106. As a result, the area of the bonding surface of the second electrode 204 insulated from the second shield electrode 206 can be increased, and the allowable range of misalignment in the bonding between the first substrate 10 and the second substrate 20 can be increased.

As described above, the second shield electrode 206 is only required to be electrically connected to at least one of the plurality of first shield electrodes 106.

As described above, according to the present embodiment, since the allowable amount of misalignment is in a range in which the first electrode 104 can be electrically connected to the second electrode 204, the allowable accuracy of alignment is greatly curbed, and even in a case where a larger misalignment occurs, a shield can be appropriately provided between the electrodes. Therefore, even in a case where the semiconductor device has a finer structure, the semiconductor device can be manufactured appropriately.

### Second Embodiment

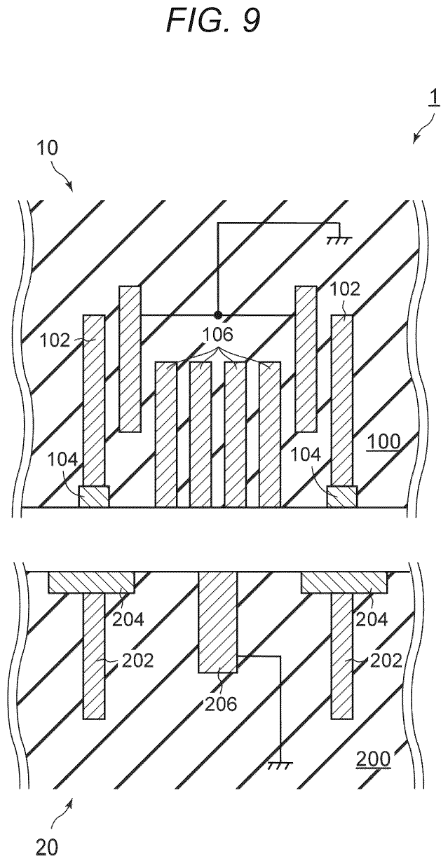

FIG. 9 is a diagram schematically illustrating a bonding surface of a semiconductor device 1 according to an embodiment. Similarly to FIG. 3, a first substrate 10 and a second substrate 20 are illustrated in a separated state. The semiconductor device 1 further includes a second shield 110 in addition to the elements of the above-described embodiment.

The second shield 110 is arranged between a first shield electrode 106 and a first wiring 102 while being insulated from both of these components. Further, while the drawing illustrates a state in which the second shield 110 is provided between the first shield electrode 106 and the first electrode 104 without overlapping these components, the present invention is not limited thereto, and a part of the second shield 110 may be arranged between the first shield electrode 106 and the first electrode 104 while being insulated from both of these components. In addition, the second shield 110 is also arranged while being insulated from the bonding surface between the first substrate 10 and the second substrate 20.

The second shield 110 may be connected to the ground potential. By arranging the second shield 110 controlled to the ground potential in this manner, a conductive layer having the ground potential may be provided between the first wiring 102 and the first shield electrode 106.

By providing such a second shield 110, the depth of the first shield electrode 106 from the bonding surface can be reduced. For example, in the first embodiment described above, it is desirable that the first shield electrode 106 extend between the first wirings 102. However, by providing the second shield 110 of the present embodiment, the depth of the first shield electrode 106 can be reduced, and the degree of freedom in layout in the semiconductor layer can be improved, or the semiconductor process can be simplified.

Note that while the second shield 110 is grounded in FIG. 9, the present invention is not limited thereto. As another example, the second shield 110 may be a conductor surrounded by an insulator. That is, as another example, the second shield 110 may be arranged in an insulator without being electrically connected to any potential.

### Application Example of Semiconductor Device

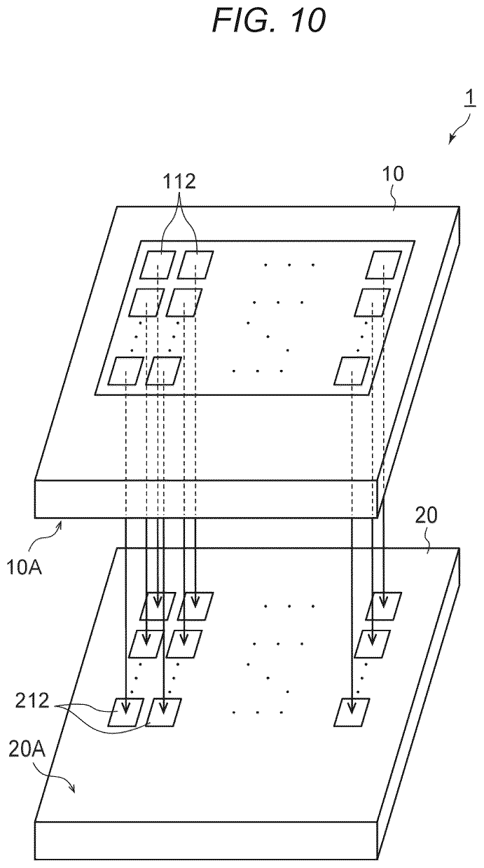

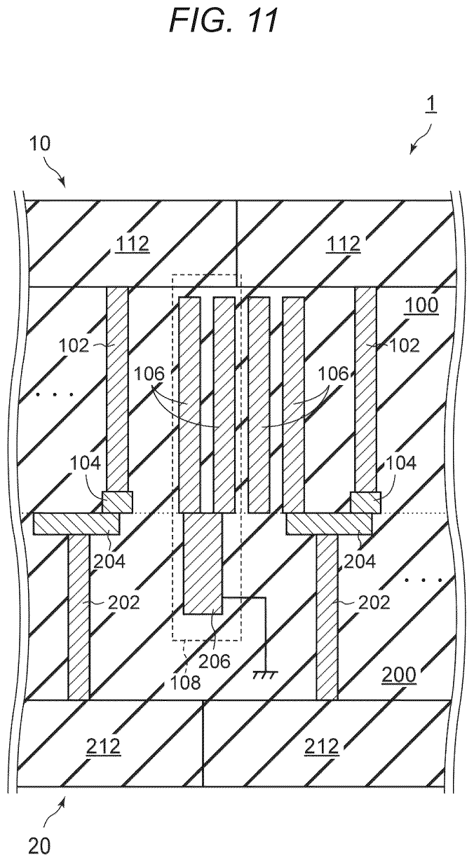

FIG. 10 is a diagram illustrating an application example of a semiconductor device 1 as a non-limiting example. The semiconductor device 1 may form a solid-state imaging element.

A first substrate 10 includes a plurality of light receiving elements 112 including photodiodes and the like. The light receiving element 112 forms a light receiving pixel. A second substrate 20 includes pixel circuits 212 that achieve signal processing of signals output from the respective light receiving elements 112. The first substrate 10 and the second substrate 20 form a semiconductor device 1 in which a bonding surface 10A and a bonding surface 20A are laminated on each other.

The light receiving element 112 is connected to the first electrode 104 via the first wiring 102 in FIGS. 7 to 9, for example, and the pixel circuit 212 is connected to the second electrode 204 via the second wiring 202. Then, the first electrode 104 and the second electrode 204 are bonded to each other in a state where the above-described shield electrode and shield are arranged. This bonding may be, for example, hybrid bonding.

The light receiving element 112 is miniaturized with the increase in resolution, and the corresponding pixel circuit 212 is also miniaturized accordingly. In a case where such miniaturized structures are bonded to each other, a problem of alignment in bonding occurs. However, by having the structure described in the above-described embodiment, this problem of alignment accuracy can be improved.

The presence of the shield has an effect of preventing signal degradation and improving the dynamic range, but on the other hand, alignment accuracy in consideration of the area of the shield is required. According to the embodiment of the present disclosure, it is possible to take a large allowable range of such alignment, and it is possible to further improve the yield with a structure including the shield.

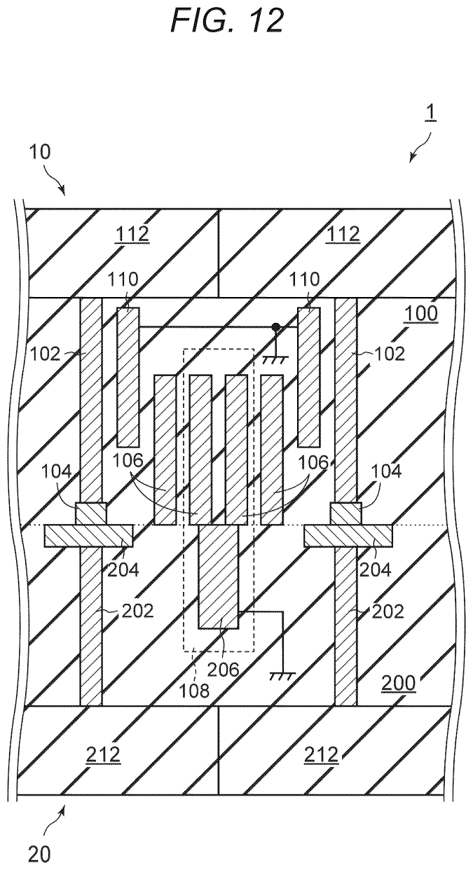

FIGS. 11 and 12 are diagrams schematically illustrating a cross section of a semiconductor device 1 in an example in which a solid-state imaging element according to an embodiment is formed. FIGS. 11 and 12 illustrate semiconductor devices 1 having the configurations of FIGS. 3 and 9, respectively.

As illustrated in these drawings, a light receiving element 112 is connected to a first wiring 102, and outputs a signal based on the intensity of received light to a second substrate 20 via a first electrode 104. This signal propagates to a second wiring 202 via a second electrode 204 and is output to a pixel circuit 212.

In FIG. 11, a first shield 108 including a first shield electrode 106 and a second shield electrode 206 can curb signal degradation from the light receiving element 112 to the bonding region of the second substrate 20.

In FIG. 12, a second shield 110 can curb signal degradation from the light receiving element 112 to the first wiring 102, and a first shield 108 can curb signal degradation from the bonding region of the first substrate 10 to the bonding region of the second substrate 20.

Therefore, a signal corresponding to the intensity of light received by the light receiving element 112 is appropriately output to the pixel circuit 212 via the first wiring 102, the first electrode 104, the second electrode 204, and the second wiring 202 in a state where the influence of the parasitic capacitance or the like due to the fine structure is curbed.

Use of the structure of the present disclosure in a solid-state imaging element is a non-limiting example. As another non-limiting example, another semiconductor device in which miniaturization of elements forming a circuit is desired, a display device and a memory device can also have a similar configuration, so that a signal can be propagated in a state in which signal degradation caused by parasitic capacitance or the like due to a fine structure is curbed.

Note that in a case where the semiconductor device 1 is a solid-state imaging element, as described above, a layer including a photodiode and a layer including a pixel circuit and a processing circuit may be laminated, or a layer including a storage region may be further laminated. That is, instead of two layers, three or more layers may be laminated to form the semiconductor device 1. In addition, the combination of the component of each layer is not limited thereto, and each layer may be formed and laminated in a combination capable of appropriately exhibiting its function.

### Method of Manufacturing Semiconductor Device

Next, a manufacturing method related to lamination of the aforementioned semiconductor device 1 will be described. For example, a case where the second shield 110 illustrated in FIG. 8 is provided will be described, but other forms can be similarly manufactured.

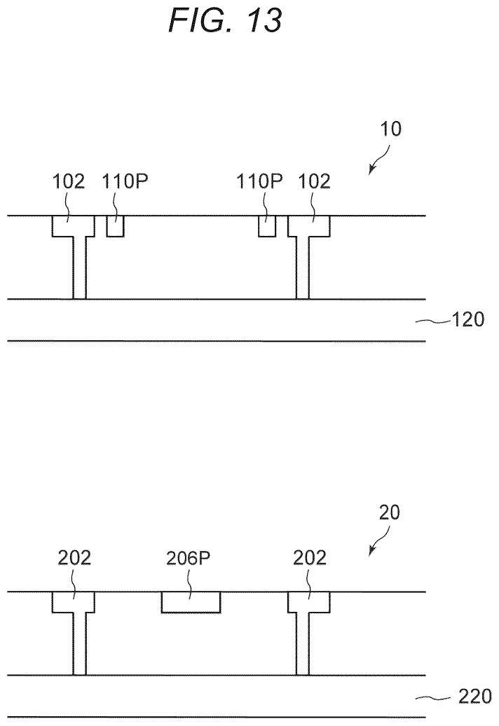

FIGS. 13 to 15 are diagrams illustrating a manufacturing process of the semiconductor device 1 according to the embodiment. In the drawings of the manufacturing process, the upper drawing illustrates the manufacturing process of the first substrate 10, and the lower drawing illustrates the manufacturing process of the second substrate 20.

First, as illustrated in FIG. 13, a first semiconductor layer 120 that is a component of the first substrate 10 is formed on a semiconductor substrate, and similarly, a second semiconductor layer 220 that is a component of the second substrate 20 is formed on another semiconductor substrate. In the example of the solid-state imaging element, the first semiconductor layer 120 may include a photodiode in at least a part thereof, and the second semiconductor layer 220 may include a pixel circuit in at least a part thereof.

Next, an insulating layer such as SiO₂ is formed on each of the upper surfaces of the first semiconductor layer 120 and the second semiconductor layer 220.

Next, by etching the insulating layer and forming a metal film, in the first substrate 10, the first wiring 102 is formed so as to be appropriately connected to the components formed in the first semiconductor layer 120. Similarly, in the second substrate 20, the second wiring 202 is formed so as to be appropriately connected to the components formed in the second semiconductor layer 220.

On the upper surface of each semiconductor substrate, an electrode for connection with wirings or the like in the next process is formed. In particular, the second shield 110 and electrodes 110P and 206P for controlling the second shield electrode 206 to a predetermined potential (for example, the ground potential) are appropriately formed.

These wirings and electrodes are formed, for example, by performing masking in accordance with the shape of the wirings, the electrodes, and the like, then performing anisotropic or isotropic etching to form trenches, forming a metal film in the formed trenches, and then performing polishing. The method of forming the insulating film, masking, etching, metal formation, and polishing is not particularly limited as long as it is a method of appropriately forming the wirings and the electrodes.

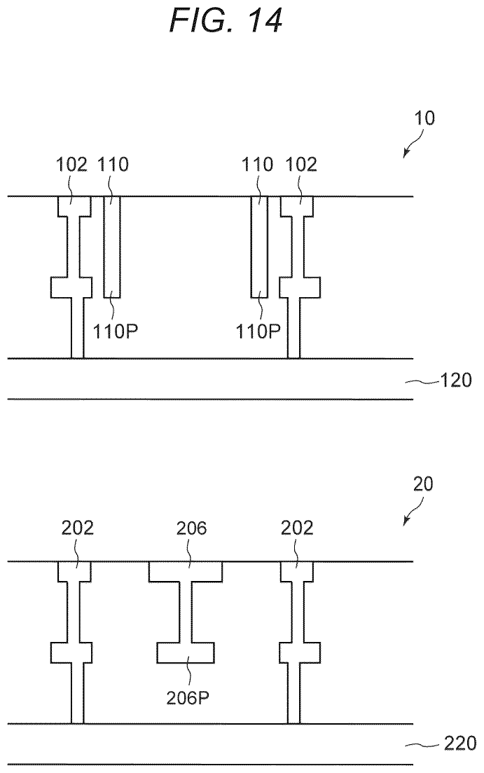

Next, an insulating film is formed on the upper surface of each substrate illustrated in FIG. 13. Subsequently, by forming metal in the insulating film formed as illustrated in FIG. 14, the first wiring 102 and the second shield 110 are formed in the first substrate 10, and the second wiring 202 and the second shield electrode 206 are formed in the second substrate 20. This forming process can be performed in a manner similar to that of the foregoing process.

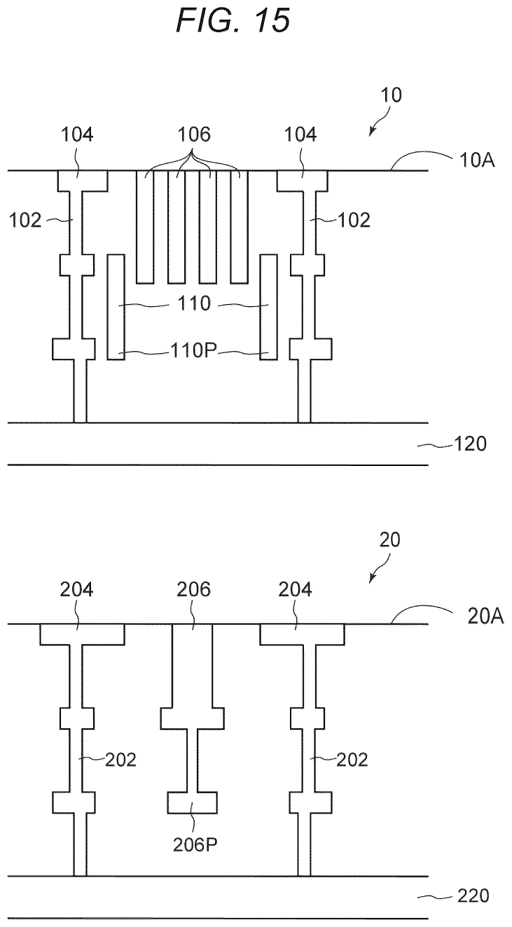

Next, an insulating film is formed on the upper surface of each substrate illustrated in FIG. 14. Subsequently, the first wiring 102, the first electrode 104, the first shield electrode 106, the second wiring 202, the second electrode 204, and the second shield electrode 206 are formed by forming metal in the insulating film formed as illustrated in FIG. 15. This forming process can also be performed in a manner similar to that of the foregoing process.

Note that in the formation of the first shield electrode 106, anisotropic etching may be performed so as to exceed the thickness of the insulating film formed at the time of shifting from the process of FIG. 14 to the process of FIG. 15 after masking, thereby forming a metal such that at least a part of the second shield 110 is arranged between the first shield electrode 106 and the first wiring 102. This process may be a mode of forming a part of the first shield electrode 106 at the timing of forming the connection electrode of the wiring in FIG. 14.

At this timing, the second shield 110 may be grounded via the electrode 110P or connected to a predetermined potential. Similarly, the second shield electrode 206 may be grounded via the electrode 206P or connected to a predetermined potential. This grounding or the like may be executed after the bonding between the first substrate 10 and the second substrate 20 is completed.

Thereafter, the bonding surfaces 10A and 20A of the first substrate 10 and the second substrate 20 are bonded to each other. Through this process, the first electrode 104 and the second electrode 204 are electrically connected appropriately, and the first shield electrode 106 and the second shield electrode 206 are electrically connected. The bonding may be hybrid bonding.

In the case of performing hybrid bonding, isotropic etching may be performed after masking so as to provide a recess in an insulator to be each formed bonding surface, a metal to be an electrode may be embedded after removing the mask, and then the bonding surfaces 10A and 20A may be formed by appropriately polishing the upper surface.

As a non-limiting example, the bonding may be performed in a chip on chip (CoC) process in which chips are cut out from both wafers and then bonded. As a non-limiting example, the bonding may be performed in a chip on wafer (CoW) process in which chips are cut out from one wafer and then bonded to the other wafer. As a non-limiting example, the bonding may be performed in a wafer on wafer (WoW) process of bonding both wafers and then cutting out the wafers as chips.

For example, in FIG. 15, the width of the first electrode 104 is 100 nm, the width of the second electrode 204 is 300 nm, the distance between the first electrode 104 and the nearest first shield electrode 106 is 100 nm, and the distance between the second electrode 204 and the second shield electrode 206 is 150 nm. In this case, the allowable misalignment amount between the first electrode 104 and the second electrode 204 is <100 nm. On the other hand, as can be seen from the drawing, the allowable misalignment amount between the first shield electrode 106 and the second shield electrode 206 can be made larger than that.

Therefore, it is possible to increase the allowable misalignment amount as compared with a case where one shield electrode is arranged with a width of about the wiring in each of the first substrate 10 and the second substrate 20. Therefore, the allowable misalignment amount in the hybrid bonding process can be increased after the shield electrode is appropriately arranged.

### APPLICATION EXAMPLE

The technology according to the present disclosure can be applied to various products. For example, the technology according to the present disclosure may also be implemented as a device mounted on any kind of mobile body such as an automobile, an electric automobile, a hybrid electric automobile, a motorcycle, a bicycle, a personal mobility, an airplane, a drone, a ship, a robot, a construction machine, an agricultural machine (tractor), or the like.

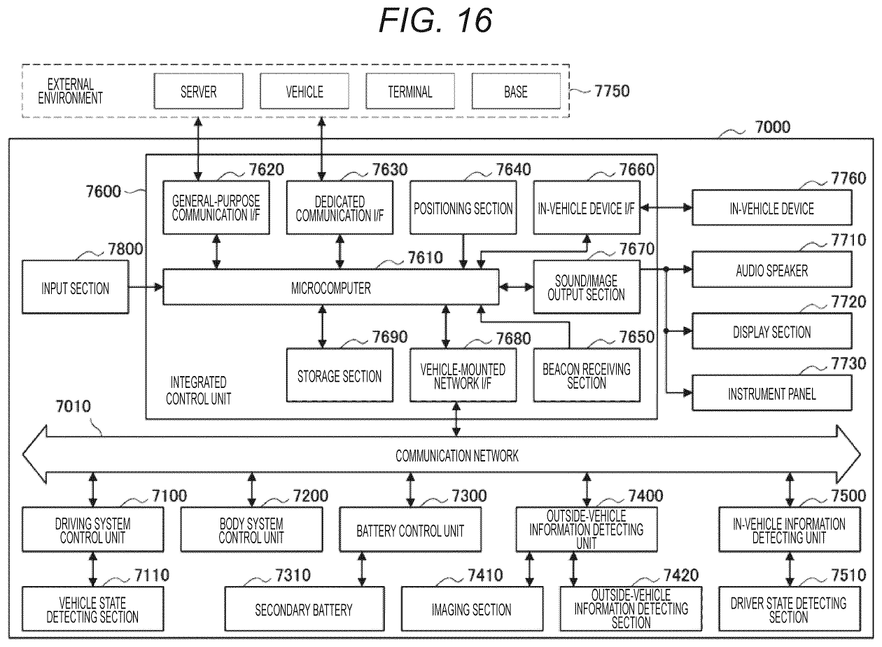

FIG. 16 is a block diagram illustrating a schematic configuration example of a vehicle control system 7000 which is an example of a moving body control system to which the technology according to the present disclosure can be applied. The vehicle control system 7000 includes a plurality of electronic control units connected to each other via a communication network 7010. In the example illustrated in FIG. 16, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 16 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

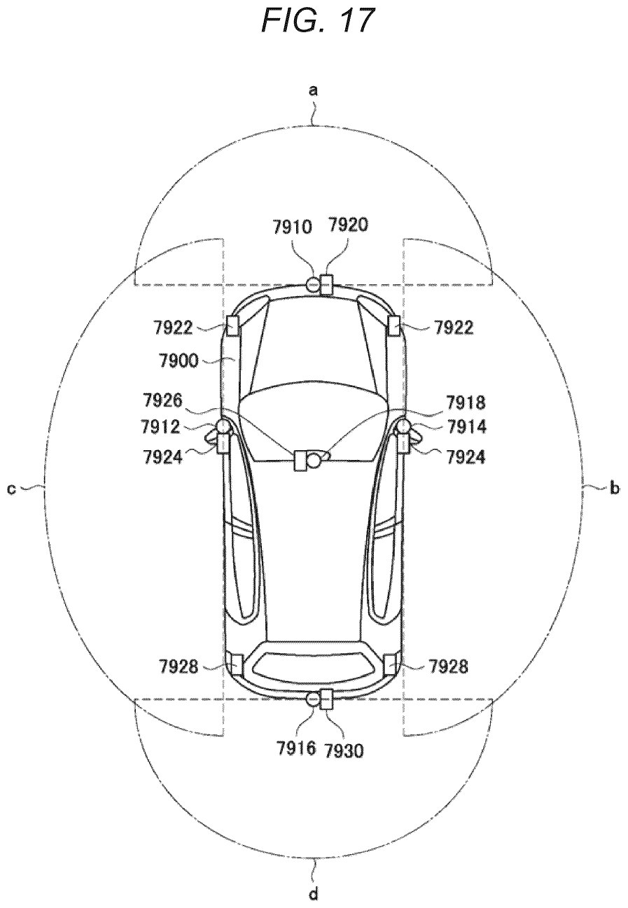

Here, FIG. 17 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 17 illustrates an example of the imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 16, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example in FIG. 16, an audio speaker 7710, a display section 7720, and an instrument panel 7730 are exemplified as the output devices. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that in the example illustrated in FIG. 16, at least two control units connected to each other via the communication network 7010 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

In the vehicle control system 7000 described above, the semiconductor device 1 according to the present embodiment described with reference to FIGS. 1 to 15 can be applied to the imaging section 7410 or the display section 7720 of the application example illustrated in FIG. 16.

The embodiments described above may have the following modes.
(1)

A semiconductor device including
a first substrate and a second substrate, in which:
the first substrate includes
a plurality of first wirings insulated from each other,
a plurality of first electrodes connected to the first wirings and insulated from each other, and
a first shield electrode arranged at least between the plurality of first electrodes and insulated from the first electrode;
the second substrate includes
a plurality of second wirings insulated from each other,
a plurality of second electrodes connected to the second wirings and insulated from each other, and
a second shield electrode arranged at least between the plurality of second electrodes and insulated from the second electrode;
the first electrode and the second electrode are electrically connected by hybrid bonding; and
the first shield electrode and the second shield electrode are electrically connected by hybrid bonding to form a first shield.
(2)

The semiconductor device according to (1), in which
the first substrate further includes, between the first shield and the first wiring, or between the first shield and the first wiring and the first electrode, a second shield that is a conductor insulated from the first wiring, the first electrode, the first shield, and a bonding surface between the first substrate and the second substrate.
(3)

The semiconductor device according to (2), in which
the second shield is grounded.
(4)

The semiconductor device according to (2), in which
the second shield is arranged in an insulator so as not to be connected to any potential.
(5)

The semiconductor device according to any one of (1) to (4), in which
a potential of the first shield is controlled to a predetermined potential.
(6)

The semiconductor device according to (5), in which
the first shield is grounded.
(7)

The semiconductor device according to any one of (2) to (4), in which
the first shield is controlled to a predetermined potential on the second substrate side.
(8)

The semiconductor device according to (7), in which
the first shield is grounded.
(9)

The semiconductor device according to any one of (1) to (8), in which
a plurality of the first shield electrodes is arranged while being insulated between the adjacent first electrodes, and
the second shield electrode is electrically connected to at least one of the plurality of first shield electrodes.
(10)

The semiconductor device according to (9), in which
at a bonding surface between the first substrate and the second substrate, a distance between the first shield electrodes is shorter than a width of the second shield electrode.
(11)

The semiconductor device according to (10), in which
at a bonding surface between the first substrate and the second substrate, a width of the first electrode is narrower than a width of the second electrode, and a distance between the second electrode and the second shield electrode is shorter than a width of the first electrode.
(12)

The semiconductor device according to any one of (1) to (11), in which
the first wiring, the first electrode, the first shield electrode, the second wiring, the second electrode, the second shield electrode, and the first shield include copper.
(13)

The semiconductor device according to (3), in which
the second shield includes copper.
(14)

The semiconductor device according to any one of (1) to (13), in which
the first substrate includes a plurality of pixels each including a photodiode, and
each of the pixels is connected to the first electrode via the first wiring.
(15)

The semiconductor device according to (14), in which
the second substrate includes a plurality of pixel circuits that process signals output from the pixels, and
each of the pixel circuits is connected to the second electrode via the second wiring.
(16)

The semiconductor device according to any one of (1) to (15), in which
the hybrid bonding is bonding in which at least a part of an electrode formed in an interlayer insulating film on a bonding surface of the first substrate and an electrode formed in an interlayer insulating film on a bonding surface of the second substrate are directly connected to each other.
(17)

A method of manufacturing a semiconductor device formed by laminating a first substrate and a second substrate, the method including:
forming, on the first substrate, a plurality of first wirings, a plurality of first electrodes connected to the first wirings, and a plurality of first shield electrodes insulated from the first wirings and the first electrodes between the adjacent first electrodes;
forming, on the second substrate, a plurality of second wirings, a plurality of second electrodes connected to the second wirings, and the second shield electrode insulated from the second wirings and the second electrodes between the adjacent second electrodes; and
electrically connecting the first electrode and the second electrode, and at least one of the first electrodes and the second shield electrode.
(18)

The method of manufacturing a semiconductor device according to (17), in which
the electrode of the first substrate and the electrode of the second substrate are electrically connected by hybrid bonding.
(19)

The method of manufacturing a semiconductor device according to (17) or (18), in which
the first substrate and the second substrate are bonded in a form of chip on chip (CoC), chip on wafer (CoW), or wafer on wafer (WoW).
(20)

The method of manufacturing a semiconductor device according to any one of (17) to (19), in which:
a photodiode is formed on the first substrate;
a pixel circuit is formed on the second substrate; and
the first electrode connected to the photodiode via the first wiring and the second electrode connected to the pixel circuit via the second wiring are electrically connected.

Aspects of the present disclosure are not limited to the above-described embodiments, and include various conceivable modifications. The effects of the present disclosure are not limited to the above-described contents. The components in each of the embodiments may be appropriately combined and applied. That is, various additions, modifications, and partial deletions can be made without departing from the conceptual idea and gist of the present disclosure derived from the contents defined in the claims and equivalents thereof.

In the above-described embodiment, a solid-state imaging device has been described as a semiconductor device as an example, but this is merely a non-limiting example. In a semiconductor device formed by laminating layers, it is important to connect wirings in hybrid bonding. In addition, the wiring becomes finer, and the importance of the shield also increases. As described above, each of the above-described embodiments can be similarly applied to a semiconductor device to be subjected to hybrid bonding that requires miniaturization. The semiconductor device according to each of the above-described embodiments can also be applied to a display device or a memory device as another non-limiting example.

### REFERENCE SIGNS LIST

1 Semiconductor device
10 First substrate
100 Insulator
102 First wiring
104 First electrode
106 First shield electrode
108 First shield
110 Second shield
112 Light receiving element
120 First semiconductor layer
20 Second substrate
200 Insulator
202 Second wiring
204 Second electrode
206 Second shield electrode
212 Pixel circuit
220 Second semiconductor layer
30 Third substrate

What is claimed is:

1. A semiconductor device, comprising
a first substrate and a second substrate, wherein:
the first substrate includes
a plurality of first wirings insulated from each other,
a plurality of first electrodes connected to the first wirings and insulated from each other, and
a first shield electrode arranged at least between the plurality of first electrodes and insulated from the first electrode;
the second substrate includes
a plurality of second wirings insulated from each other,
a plurality of second electrodes connected to the second wirings and insulated from each other, and
a second shield electrode arranged at least between the plurality of second electrodes and insulated from the second electrode;
the first electrode and the second electrode are electrically connected by hybrid bonding; and
the first shield electrode and the second shield electrode are electrically connected by hybrid bonding to form a first shield.

2. The semiconductor device according to claim 1, wherein
the first substrate further includes, between the first shield and the first wiring, or between the first shield and the first wiring and the first electrode, a second shield that is a conductor insulated from the first wiring, the first electrode, the first shield, and a bonding surface between the first substrate and the second substrate.

3. The semiconductor device according to claim 2, wherein
the second shield is grounded.

4. The semiconductor device according to claim 2, wherein
the second shield is arranged in an insulator so as not to be connected to any potential.

5. The semiconductor device according to claim 1, wherein
a potential of the first shield is controlled to a predetermined potential.

6. The semiconductor device according to claim 5, wherein
the first shield is grounded.

7. The semiconductor device according to claim 2, wherein
the first shield is controlled to a predetermined potential on the second substrate side.

8. The semiconductor device according to claim 7, wherein
the first shield is grounded.

9. The semiconductor device according to claim 1, wherein
a plurality of the first shield electrodes is arranged while being insulated between the adjacent first electrodes, and
the second shield electrode is electrically connected to at least one of the plurality of first shield electrodes.

10. The semiconductor device according to claim 9, wherein
at a bonding surface between the first substrate and the second substrate, a distance between the first shield electrodes is shorter than a width of the second shield electrode.

11. The semiconductor device according to claim 10, wherein
at a bonding surface between the first substrate and the second substrate, a width of the first electrode is narrower than a width of the second electrode, and a distance between the second electrode and the second shield electrode is shorter than a width of the first electrode.

12. The semiconductor device according to claim 1, wherein
the first wiring, the first electrode, the first shield electrode, the second wiring, the second electrode, the second shield electrode, and the first shield include copper.

13. The semiconductor device according to claim 3, wherein
the second shield includes copper.

14. The semiconductor device according to claim 1, wherein
the first substrate includes a plurality of pixels each including a photodiode, and
each of the pixels is connected to the first electrode via the first wiring.

15. The semiconductor device according to claim 14, wherein
the second substrate includes a plurality of pixel circuits that process signals output from the pixels, and
each of the pixel circuits is connected to the second electrode via the second wiring.

16. The semiconductor device according to claim 1, wherein
the hybrid bonding includes bonding in which at least a part of an electrode formed in an interlayer insulating film on a bonding surface of the first substrate and an electrode formed in an interlayer insulating film on a bonding surface of the second substrate are directly connected to each other.

17. A method of manufacturing a semiconductor device formed by laminating a first substrate and a second substrate, the method comprising:
forming, on the first substrate, a plurality of first wirings, a plurality of first electrodes connected to the first wirings, and a plurality of first shield electrodes insulated from the first wirings and the first electrodes between the adjacent first electrodes;
forming, on the second substrate, a plurality of second wirings, a plurality of second electrodes connected to the second wirings, and the second shield electrode insulated from the second wirings and the second electrodes between the adjacent second electrodes; and
electrically connecting the first electrode and the second electrode, and at least one of the first electrodes and the second shield electrode.

18. The method of manufacturing a semiconductor device according to claim 17, wherein
the electrode of the first substrate and the electrode of the second substrate are electrically connected by hybrid bonding.

19. The method of manufacturing a semiconductor device according to claim 17, wherein
the first substrate and the second substrate are bonded in a form of chip on chip (CoC), chip on wafer (CoW), or wafer on wafer (WoW).

20. The method of manufacturing a semiconductor device according to claim 17, wherein:
a photodiode is formed on the first substrate;
a pixel circuit is formed on the second substrate; and
the first electrode connected to the photodiode via the first wiring and the second electrode connected to the pixel circuit via the second wiring are electrically connected.
